(19) United States
(12) Patent Application Publication
(10) Pub. No.: US 2026/0164999 A1
(43) Pub. Date: Jun. 11, 2026

(54) DISPLAY PANEL, MANUFACTURING METHOD FOR DISPLAY PANEL, AND ELECTRONIC DEVICE

(71) Applicants: Hefei Visionox Technology Co., Ltd., Hefei (CN); Visionox Technology Inc., Kunshan (CN); Hefei Visionox Electronics Co., Ltd., Hefei (CN)

(72) Inventors: Zhiwei ZHOU, Hefei (CN); Yuting FU, Hefei (CN); Liusong NI, Hefei (CN); Bowen YANG, Hefei (CN); Zhen FU, Hefei (CN)

(73) Assignees: Hefei Visionox Technology Co., Ltd., Hefei (CN); Visionox Technology Inc., Kunshan (CN); Hefei Visionox Electronics Co., Ltd., Hefei (CN)

(21) Appl. No.: 19/432,210

(22) Filed: Dec. 24, 2025

Related U.S. Application Data
(63) Continuation of application No. PCT/CN2025/129554, filed on Oct. 23, 2025.

(30) Foreign Application Priority Data
Dec. 10, 2024 (CN) 202411823766.X
Aug. 5, 2025 (CN) 202511094953.3

(51) Int. Cl. H10K 59/80; H10K 59/12; H10K 59/122; H10K 59/131

(52) U.S. Cl. CPC H10K 59/873; H10K 59/1201; H10K 59/122; H10K 59/131; H10K 59/8723

(57) ABSTRACT

Disclosed are a display panel, a manufacturing method therefor, and a display device. The display panel includes a substrate, a drive circuit layer, a first organic layer, an isolation structure, and a plurality of light-emitting devices, as well as a structural function layer, a first encapsulation layer, and a second encapsulation layer sequentially stacked. The drive circuit layer is disposed on the substrate, and the first organic layer is disposed on the side, facing away from the drive circuit layer, of the substrate. In the first region, the first organic layer is isolated from the first encapsulation layer by the structural function layer. An orthographic projection of the structural function layer on the substrate is continuous in the first region. This arrangement can prevent moisture entering from entering a damaged area of the second encapsulation layer to corrode the drive circuit layer.

### CROSS-REFERENCE TO RELATED DISCLOSURES

This application is a continuation of International Application No. PCT/CN2025/129554, filed on Oct. 23, 2025, which claims priority to Chinese Patent Application No. 202411823766.X, filed on Dec. 10, 2024, and Chinese Patent Application No. 2025110949533, filed on Aug. 5, 2025. All of the aforementioned patent applications are hereby incorporated by reference in their entireties.

### FIELD

The present disclosure generally relates to the field of display technologies, and in particular, to a display panel and a manufacturing method therefor, and an electronic device.

### BACKGROUND

With a widespread application of electronic display devices, people have higher requirements for various performance characteristics of the electronic display devices. Display panels based on technologies such as Organic Light Emitting Diode (OLED) and Light Emitting Diode (LED) are widely used in various electronic display devices such as mobile phones, televisions, laptops, and desktop computers due to their advantages of high image quality, energy saving, and thin profile. In traditional display panel manufacturing processes, light-emitting pixel patterning is typically achieved using Fine Metal Mask (FMM). FMM technology is mature and has extensive mass production experience. However, FMM technology also has limitations such as limited precision, high development costs, and long development cycles. Fine Metal Mask Free technology may eliminate the limitations of traditional OLED processes on display size, resolution, and other panel performance characteristics, offering advantages of high performance, full-size capability, and agile delivery. Relevant content of the Fine Metal Mask Free technology are disclosed in Patents CN118251982A, CN116648095A, CN117062489A, CN118742138A, CN118678783A, CN118660598A, CN118675450A, CN118824188A, and CN118781966A, which may be referred to for reference.

In related technologies, packaging reliability of display panels needs to be improved.

### SUMMARY

In view of this, embodiments of the present disclosure provide a display panel and a manufacturing method therefor, and a display device, to at least partially solve the above problems.

According to the embodiments of one or more embodiments of the present disclosure, a display panel is provided. The display panel includes a substrate, a driving circuit layer, a first organic layer, an isolation structure, and a plurality of light-emitting devices, as well as a structural function layer, a first encapsulation layer, and a second encapsulation layer disposed on a side, facing away from the driving circuit layer, of the first organic layer. The driving circuit layer is disposed on the substrate; the first organic layer is disposed on a side, acing away from the substrate, of the driving circuit layer; and the structural function layer, the first encapsulation layer and the second encapsulation layer are sequentially stacked along a direction away from the driving circuit layer. In at least one first region, the first organic layer is isolated from the first encapsulation layer by the structural function layer. An orthographic projection of the structural function layer on the substrate is continuous in the first region. The structural function layer includes a first inorganic layer, and a material of the first encapsulation layer includes an organic material. A material of the second encapsulation layer includes an inorganic material. The isolation structure is located between the first organic layer and the first encapsulation layer, and a plurality of isolation openings are defined by the isolation structure. The plurality of light-emitting devices are located between the first organic layer and the first encapsulation layer, with at least part of a light-emitting device located in a corresponding one of plurality of isolation openings.

According to the embodiments of one or more embodiments of the present disclosure, a manufacturing method for a display panel is provided. The manufacturing method includes: providing a substrate, sequentially forming a driving circuit layer and a first organic layer on the substrate; baking the first organic layer; sequentially forming a structural function layer, a first encapsulation layer and a second encapsulation layer on a side, facing away from the driving circuit layer, of the first organic layer, where in a first region, the first encapsulation layer is isolated form the first organic layer by the structural function layer.

According to the embodiments of one or more embodiments of the present disclosure, a display device is provided. The display device includes the aforementioned display panel, or a display panel prepared by the aforementioned manufacturing method for the display panel.

According to the solution provided by the embodiments of the present disclosure, since the first encapsulation layer and the first organic layer are isolated by the structural function layer, direct contact between the first encapsulation layer and the first organic layer is avoided. Even if the second encapsulation layer is damaged, external moisture will be blocked by the structural function layer and cannot easily enter the first organic layer from the first encapsulation layer, thereby preventing moisture from invading the driving circuit layer through the first organic layer. Therefore, it can prevent moisture entering from a damaged area of the second encapsulation layer to corrode the driving circuit layer, thus solving a problem of display abnormalities in the display panel.

### BRIEF DESCRIPTION OF THE DRAWINGS

FIGS. 1a and 1b are schematic cross-sectional structural diagrams of display panels in related technologies, respectively.

FIG. 2 is a schematic cross-sectional structural diagram of a display panel in a first region according to an embodiment of the present disclosure.

FIG. 3 is a schematic top-view diagram of a display panel according to an embodiment of the present disclosure.

FIGS. 4a and 4b are schematic cross-sectional structural diagrams of a display panel according to an embodiment of the present disclosure, respectively.

FIG. 4c is a schematic diagram of the orthographic projection of the first opening and the second opening in the first region on the substrate in a display panel according to an embodiment of the present disclosure.

FIG. 5 is a schematic cross-sectional structural diagram of a display panel according to an embodiment of the present disclosure.

FIG. 6 is a schematic cross-sectional structural diagram of a display panel according to an embodiment of the present disclosure.

FIG. 7 is a schematic cross-sectional structural diagram of a display panel according to an embodiment of the present disclosure.

FIGS. 8a and 8b are schematic cross-sectional structural diagrams of a display panel according to an embodiment of the present disclosure, respectively.

FIG. 9 is a schematic cross-sectional structural diagram of a display panel according to an embodiment of the present disclosure.

FIG. 10 is a schematic cross-sectional structural diagram of a display panel according to an embodiment of the present disclosure.

FIGS. 11a to 11c are schematic cross-sectional structural diagrams of a display panel according to an embodiment of the present disclosure, respectively.

FIG. 11d is a schematic top plan view of a first inorganic layer according to an embodiment of the present disclosure.

FIG. 11e is a schematic plan view of a first sub-conductive layer according to an embodiment of the present disclosure.

FIG. 11f is a schematic plan view of a second sub-conductive layer according to an embodiment of the present disclosure.

FIG. 11g is a schematic plan view of a first inorganic layer according to an embodiment of the present disclosure.

FIG. 11h is a schematic cross-sectional view of a display panel according to an embodiment of the present disclosure.

FIGS. 12a to 12c are schematic cross-sectional views of a display panel according to an embodiment of the present disclosure.

FIGS. 13a to 13f are schematic cross-sectional views of a display panel according to an embodiment of the present disclosure.

FIG. 14 is a flowchart of a manufacturing method for a display panel according to an embodiment of the present disclosure.

FIGS. 15a and 15b are schematic cross-sectional views during a manufacturing method for a display panel according to an embodiment of the present disclosure.

FIGS. 16a and 16b are schematic cross-sectional views during a manufacturing method for a display panel according to an embodiment of the present disclosure.

FIG. 17 is a schematic structural diagram of a display device according to an embodiment of the present disclosure.

FIG. 18 is a flowchart of a step of forming a structural function layer on a side, facing away from a drive circuit layer, of a first organic layer according to an embodiment of the present disclosure.

FIG. 19 is a flowchart of a step of forming a structural function layer on a side, facing away from a drive circuit layer, of a first organic layer according to another embodiment of the present disclosure.

### DETAILED DESCRIPTION OF THE EMBODIMENTS

The singular forms “a”, “the”, and “that” used in the embodiments of the present disclosure and the appended claims are also intended to include plural forms, unless the context clearly indicates otherwise. It should also be understood that the term “and/or” used in the embodiments of the present disclosure includes any or all possible combinations of one or more associated listed items.

Terms such as “length”, “width”, “upper”, “lower”, “front”, “rear”, “left”, “right”, “vertical”, “horizontal”, “top”, “bottom”, “inner” and “outer” indicate orientations or positional relationships based on those shown in the accompanying drawings. These terms are used only to facilitate the description of the embodiments of the present disclosure and to simplify the description, and do not indicate or imply that the referred device or element must have a specific orientation or be constructed and operated in a specific orientation, and therefore should not be construed as limiting the embodiments of the present disclosure.

When an element or layer is referred to as being “on”, “connected to” or “coupled to” another element or layer, it may be directly on, directly connected to, or directly coupled to the other element or layer, or intervening elements or layers may be present.

Terms such as “first”, “second”, etc., are used to describe various elements, components, regions, layers, and/or sections, but these elements, components, regions, layers, and/or sections should not be limited by these terms. These terms are used to distinguish one element, component, region, layer, and/or section from another.

Terms such as “mount”, “connect”, “join”, and “fix” should be understood broadly. For example, the connection may be a fixed connection, a detachable connection, or an integral connection; it may be a mechanical connection or an electrical connection; it may be a direct connection or an indirect connection through an intermediate medium.

Specific implementation of the present disclosure will be further described below with reference to the embodiments and accompanying drawings of the present disclosure.

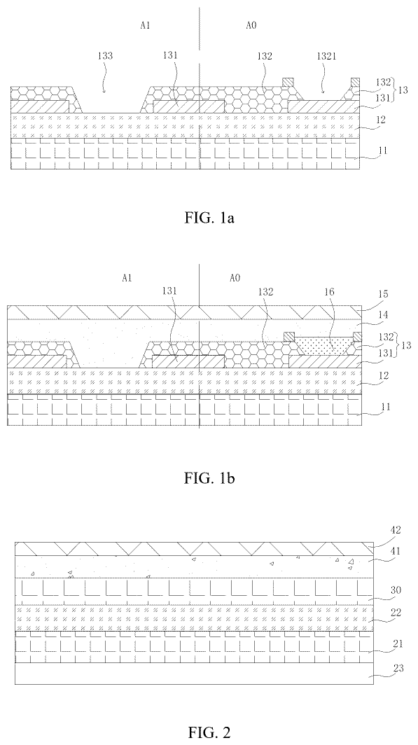

FIGS. 1a and 1b illustrate partial cross-sectional structural diagrams of a display panel in related art. The display panel includes a display region A0 and a non-display region A1. The display panel includes a driving circuit layer 11, a first organic layer 12, a function layer 13, an organic encapsulation layer 14, and an inorganic encapsulation layer 15, which are sequentially stacked. The display panel further includes a light-emitting structure 16 located in the display region A0. The light-emitting structure 16 is disposed on the function layer 13, and a first electrode portion in the function layer 13 is electrically connected to the driving circuit layer 11 through a via hole, thereby allowing the driving circuit layer 11 to control the display function of the display panel. The function layer 13 has a vent hole 133 in the non-display region, and the organic encapsulation layer 14 contacts the first organic layer 12 through the vent hole 133. During a manufacturing process of the display panel, moisture in the first organic layer 12 is removed through a baking process, and the moisture can be released through the vent hole 133.

The function layer 13 may include a first conductive layer 131 and a first inorganic layer 132 stacked. The first conductive layer 131 is located between the first organic layer 12 and the first inorganic layer 132, and the vent hole 133 penetrates through both the first conductive layer 131 and the first inorganic layer 132. The first inorganic layer 132 may include a pixel opening 1321 in the display region to expose the first conductive layer 131. At least part of the light-emitting structure 16 is disposed in the pixel opening 1321 and is in conductive contact with the first conductive layer 131 (i.e., the first electrode portion). The first conductive layer 131 can be electrically connected to the driving circuit layer 11 through a via hole in the first organic layer 12.

Due to the presence of the vent hole 133, when the inorganic encapsulation layer 15 is damaged, moisture may invade the organic encapsulation layer 14, enter the first organic layer 12 through the vent hole 133, and subsequently corrode the driving circuit layer 11, leading to display abnormalities in the display panel.

To solve the above problem, the present disclosure provides a display panel. Referring to FIG. 2, the display panel includes a substrate 23, a driving circuit layer 21, and a first organic layer 22. The driving circuit layer 21 is disposed on the substrate 23, and the first organic layer 22 is disposed on a side, facing away from the substrate 23, of the driving circuit layer 21. The display panel further includes a structural function layer 30, a first encapsulation layer 41 and a second encapsulation layer 42 sequentially stacked on a side, facing away from the driving circuit layer 21, of the first organic layer 22. The structural function layer 30, the first encapsulation layer 41 and the second encapsulation layer 42 are sequentially stacked along a direction away from the driving circuit layer 21. In the first region B11, the first organic layer 22 is isolated from the first encapsulation layer 41 by the structural function layer 30. For example, a material of the first encapsulation layer 41 includes an organic material, such as an organic insulating material; and a material of the second encapsulation layer 42 includes an inorganic material, such as an inorganic insulating material. For example, in the first region B11, the first encapsulation layer 41 and the first organic layer 22 do not contact each other. A material of the structural function layer 30 may include an inorganic material, such as an inorganic insulating material or an inorganic conductive material, etc. For example, the inorganic conductive material may include a metal material, or metal oxide, etc., and the inorganic insulating material may include silicon oxide, or silicon nitride, etc. A material of the first organic layer 22 may include an organic insulating material.

For example, in the first region B11, an orthographic projection of the structural function layer 30 on the substrate 23 is continuous. The structural function layer 30 may include a single-layer film or multi-layer films. The structural function layer 30 may include a plurality of film layers. In the first region B11, the orthographic projection of the structural function layer 30 on the substrate 23 may be a union of orthographic projections of the plurality of film layers in the structural function layer 30 on the substrate 23. The structural function layer 30 may be a single film layer. In the first region B11, the orthographic projection of the structural function layer 30 on the substrate 23 is continuous, meaning that the structural function layer 30 continuously covers the entire first region B11 without any openings in the first region B11. The structural function layer 30 may include a plurality of film layers. For example, in the first region B11, the orthogonal projection of the structural function layer 30 on the substrate 23 is continuous, meaning that each film layer in the multi-layer structure entirely and continuously covers the first region B11. In one embodiment, in the first region B11, one film layer may be provided with an opening, and another film layer covers the opening. In one embodiment, in the first region B11, each of the plurality of film layers is provided with an opening. With the openings in different film layers arranged in a staggered manner, each opening is covered by other film layers in the structural function layer 30. This arrangement may ensure that in the first region B11, the first organic layer 22 is isolated from the first encapsulation layer 41 in the first region B11 by the structural function layer 30.

For example, the structural function layer 30 may include a first inorganic layer 32. The first inorganic layer 32 is capable of blocking moisture transmission.

Through the above technical solution, since the first encapsulation layer 41 and the first organic layer 22 are isolated by the structural function layer 30 in the first region B11, direct contact between the first encapsulation layer 41 and the first organic layer 22 is avoided. Even if the second encapsulation layer 42 is damaged, external moisture will be blocked by the structural function layer 30, making it difficult for moisture to enter the first organic layer 22 from the first encapsulation layer 41, thereby preventing moisture from invading the drive circuit layer 21 through the first organic layer 22. This prevents moisture from entering a damaged area of the second encapsulation layer 42 to corrode the drive circuit layer 21, thus solving a problem of display abnormalities in the display panel. For example, no organic layer is provided between the first encapsulation layer 41 and the first organic layer 22 in the first region B11. For example, in the first region B11, the first encapsulation layer 41 and the first organic layer 22 are completely isolated by inorganic materials in the structural function layer 30. For example, in the first region B11, the structural function layer 30 is in contact with the first encapsulation layer 41. For example, in the first region B11, the structural function layer 30 is in contact with the first organic layer 22.

For example, the first region B11 may be part or all of the non-display region. The first region B11 may be located in one or more border regions, such as two, three, or four border regions, for example, one or more of a left border region, a right border region, a top border region, and a bottom border region. The first region B11 may be a closed ring. For example, it may be located in the left border region, the right border region, the top border region and the bottom border region. In one embodiment, the first region B11 may be an open ring. For example, the first region B11 may be located in the left border region, the right border region and the top border region. In one embodiment, the first region B11 may be an open ring. For example, the first region B11 may be located in the left border region, the right border region, the top border region and part of the bottom border region. There may be one or more first regions B11, such as two, three, or four, for example, different first regions correspond to different border regions. Each first region B11 in at least one first region B11 may correspond to a border region. A shape of the first region B11 may be rectangular or an irregular shape, etc. For example, a driver chip may be disposed in the bottom border region.

For example, the first region B11 may include part or all of the display region.

For example, the first region B11 may include part or all of the display region, and part or all of the non-display region.

For example, the first region B11 is located between the display region and a light-transmitting region. The first region B11 may be a closed ring or an open ring. The light-transmitting region of the display panel may be provided with light-transmitting holes. The light-transmitting region of the display panel may be provided with optical components, which may include one or more of a camera, a fingerprint recognition module, an infrared sensor, and an ambient light detection module, etc.

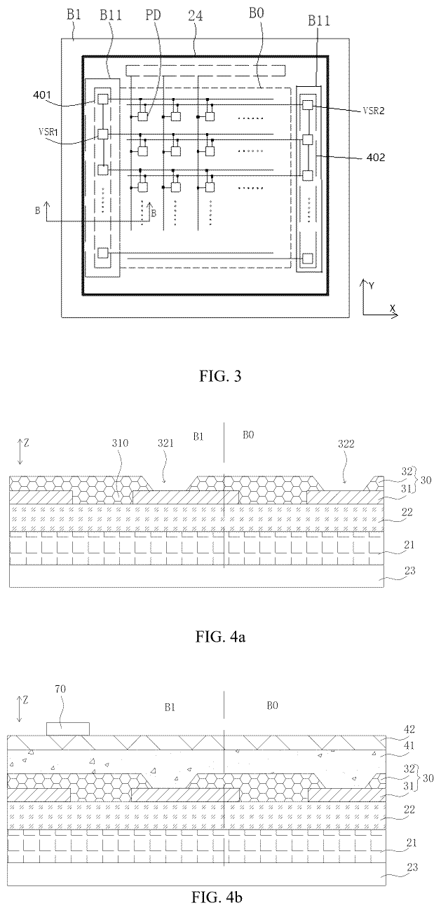

A gate driving circuit is arranged in the driving circuit layer 21. Referring to FIG. 3, the gate driving circuit may include a scan circuit 401, or an emission control circuit 402, or a scan circuit 401 and an emission control circuit 402. The scan circuit 401 may be connected to the pixel circuit PD through scan lines. The scan circuit 401 is configured to output scan signals to the pixel circuit PD. The emission control circuit 402 is connected to the pixel circuit PD through light emission control lines. The emission control circuit 402 is configured to output light emission control signals to the pixel circuit. The gate driving circuit may include a plurality of cascaded shift registers VSR. An output terminal of the shift register VSR is connected to the pixel circuit PD. The scan circuit 401 may include a plurality of cascaded shift registers VSR1. The emission control circuit 402 may include a plurality of cascaded shift registers VSR2. The first region B11 may be provided with a plurality of cascaded shift registers. The first region B11 may be provided with a gate drive circuit. A same first region B11 may be provided with the scan circuit 401, or the emission control circuit 402, or the scan circuit 401 and the emission control circuit 402. The scan circuit 401 may be located in the first border region, or the second border region, or the first border region and the second border region. The emission control circuit 402 may be located in the first border region, or the second border region, or the first border region and the second border region. The first border region and the second border region are located on opposite sides of the display region, for example, they may be the left border region and the right border region.

In a possible implementation, referring to FIGS. 3, 4a, 4b, and 4c, the display panel includes a display region B0 and a non-display region B1, and the non-display region B1 includes a first region B11. In the first region B11, the first organic layer 22 is isolated from the first encapsulation layer 41 by the structural function layer 30. The structural function layer 30 includes a first conductive layer 31 and a first inorganic layer 32 stacked along a thickness direction Z of the substrate 23. The first conductive layer 31 is provided with a first opening 310 in the first region B11, and the first inorganic layer 32 is provided with a second opening 321 in the first region B11. An orthographic projection of the first opening 310 on the substrate 23 is located outside an orthographic projection of the second opening 321 on the substrate 23, and the orthographic projection of the structural function layer 30 on the substrate 23 is continuous in the first region B11. That is, the orthographic projection of the first opening 310 on the substrate 23 does not overlap with the orthographic projection of the second opening 321 on the substrate 23, and the first opening 310 and the second opening 321 are arranged in a staggered manner. Thus, in the first region B11 or the non-display region B1, the first encapsulation layer 41 and the first organic layer 22 are isolated by the first conductive layer 31 at the second opening 321 and the first inorganic layer 32 at the first opening 310, without direct contact. FIG. 4c shows a schematic diagram of the orthographic projections of the first opening 310 and the second opening 321 on the substrate in the first region B11. For example, a total coverage area of the orthographic projections of the first inorganic layer 32 and the first conductive layer 31 on the substrate 23 in the first region B11 equals an area of the first region B11. For example, the orthographic projection of the first opening 310 on the substrate 23 is located within an orthographic projection of the first inorganic layer 32 on the substrate 23. For example, the orthographic projection of the second opening 321 on the substrate 23 is located within an orthographic projection of the first conductive layer 31 on the substrate 23.

For example, a material of the first conductive layer 31 includes a metal material. For example, a material of the first inorganic layer 32 includes an inorganic insulating material.

For example, a plurality of first openings 310 may be arranged along a first direction X. The plurality of first openings 310 may be arranged along a second direction Y. The first direction X and the second direction Y intersect, for example, perpendicularly. The plurality of first openings 310 may be arranged in an array.

For example, a plurality of second openings 321 may be arranged along the first direction X. For example, the plurality of second openings 321 may be arranged along the second direction Y. The first direction X and the second direction Y intersect, for example, perpendicularly. The plurality of second openings 321 may be arranged in an array.

For example, the plurality of first openings 310 and the plurality of second openings 321 may be alternately arranged along the first direction X. The plurality of first openings 310 and the plurality of second openings 321 may be alternately arranged along the second direction Y.

In an example, the first conductive layer 31 and the first inorganic layer 32 are sequentially stacked along a direction away from the drive circuit layer 21, with part of the first conductive layer 31 exposed in the second opening 321.

The first inorganic layer 32 provided in the present disclosure may be an inorganic insulating layer.

The non-display region B1 of the display panel surrounds the display region B0. The non-display region B1 may include a plurality of regions, such as a chin region, a bonding region, and a border region. The first region B11 in the present disclosure may be a partial region or an entire region of the non-display region. The first region B11 may include a border region located on at least one side of the display region B0. For example, when there are a plurality of first regions B11, two first regions B11 may be respectively a first border region and a second border region located on opposite sides of the display region B0. The first border region and the second border region may be arranged along an extension direction of gate lines. The gate lines may include scan lines, or emission control lines, or the scan lines and the emission control lines.

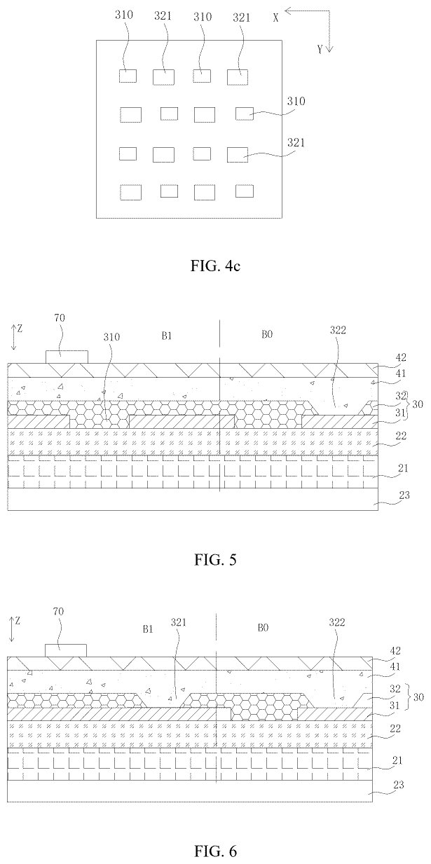

In a possible implementation, referring to FIG. 5, the display panel includes a display region B0 and a non-display region B1, where the non-display region B1 includes a first region B11. In the first region B11, a first organic layer 22 is isolated from the first encapsulation layer 41 by a structural function layer 30. The structural function layer 30 includes a first conductive layer 31 and a first inorganic layer 32 stacked along a thickness direction Z of the substrate 23. The first conductive layer 31 is provided with a first opening 310 in the first region B11. The first inorganic layer 32 is continuous in the first region B11, ensuring that an orthographic projection of the structural function layer 30 on the substrate 23 is continuous in the first region B11. For example, the first inorganic layer 32 continuously covers a plurality of cascaded shift registers in the first region B11. An area of the orthographic projection of the first inorganic layer 32 on the substrate 23 in the first region B11 equals an area of the first region B11. An orthographic projection of the first opening 310 on the substrate is located within the orthographic projection of the first inorganic layer 32 on the substrate. Thus, in the non-display region B1, the first encapsulation layer 41 and the first organic layer 22 can be isolated by the first inorganic layer 32 without direct contact. For example, the gate driver circuit is located within the first region B11. For example, the scan circuit 401 is located within the first region B11. For example, the emission control circuit 402 is located within the first region B11.

For example, in the first region B11, the first inorganic layer 32 continuously covers K1 cascaded shift registers, where K1 is greater than or equal to 20. For example, K1 is greater than or equal to 50. For example, K1 is greater than or equal to 100. K1 may be equal to 10, 20, 30, 40, 50, 60, 70, 80, 90, or 100, etc. For example, the area of the first region B11 is greater than or equal to an area of an orthographic projection of the corresponding gate driving circuit on the substrate 23. For example, for each first region B11 in at least one first region B11, the area of the first region B11 is greater than or equal to an area of an orthographic projection of a corresponding scan circuit 401 on the substrate 23. For example, for each first region B11 in at least one first region B11, the area of the first region B11 is greater than or equal to an area of an orthographic projection of a corresponding emission control circuit 402 on the substrate 23. For example, for each first region B11 in at least one first region B11, the area of the first region B11 is greater than or equal to a sum of areas of the orthographic projections of the corresponding scan circuit 401 and the emission control circuit 402 on the substrate 23. For example, in the first region B11, the first inorganic layer 32 continuously covers all shift registers from a first-stage shift register to a last-stage shift register in the corresponding gate driving circuit. For example, for each first region B11 in at least one first region B11, the first inorganic layer 32 in the first region B11 continuously covers all shift registers from the first-stage shift register to the last-stage shift register in the corresponding scan circuit 401, and/or the first inorganic layer 32 in the first region B11 continuously covers all shift registers from the first-stage shift register to the last-stage shift register in the corresponding emission control circuit 402.

For example, the first inorganic layer 32 does not have an opening in the first region B11. For example, the first inorganic layer 32 does not have an opening penetrating through the first inorganic layer 32 along the thickness direction of the substrate 23 in the first region B11. For example, in the first region B11 (i.e., the border region), the first inorganic layer 32 entirely or fully covers the first organic layer 22. In the first region B11 (i.e., the border region), the first inorganic layer 32 completely covers the first organic layer 22.

In a possible implementation, referring to FIG. 6, the display panel includes a display region B0 and a non-display region B1, where the non-display region B1 includes a first region B11. In the first region B11, a first organic layer 22 is isolated from a first encapsulation layer 41 by a structural function layer 30. The structural function layer 30 includes a first conductive layer 31 and a first inorganic layer 32 stacked along a thickness direction of the substrate 23. The first conductive layer 31 is continuous in the first region B11, and an orthogonal projection of the structural function layer 30 on the substrate 23 is continuous in the first region B11. For example, in the first region B11, the first conductive layer 31 continuously covers a plurality of cascaded shift registers. For example, an area of an orthogonal projection of the first conductive layer 31 on the substrate 23 in the first region B11 equals an area of the first region B11. The first inorganic layer 32 is provided with a second opening 321 in the first region B11. An orthogonal projection of the second opening 321 on the substrate 23 is located within the orthogonal projection of the first conductive layer 31 on the substrate 23. Thus, in the first region B11 or the non-display region B1, the first encapsulation layer 41 and the first organic layer 22 can be isolated by the first conductive layer 31 without direct contact. For example, in the first region B11, the first conductive layer 31 continuously covers all shift registers from a first-stage shift register to a last-stage shift register in a corresponding gate driver circuit. For example, in each first region B11 of at least one first region B11, the first conductive layer 31 continuously covers all shift registers from a first-stage shift register to a last-stage shift register in a corresponding scan circuit 401, and/or the first conductive layer 31 continuously covers all shift registers from the first-stage shift register to the last-stage shift register in the corresponding emission control circuit 402.

For example, the first conductive layer 31 has no opening in the first region B11. For example, the first conductive layer 31 has no opening penetrating through the first conductive layer 31 along the thickness direction of the substrate 23 in the first region B11. For example, in the first region B11 (i.e., the border region), the first conductive layer 31 entirely or fully covers the first organic layer 22. In the first region B11 (i.e., the border region), the first conductive layer 31 completely covers the first organic layer 22.

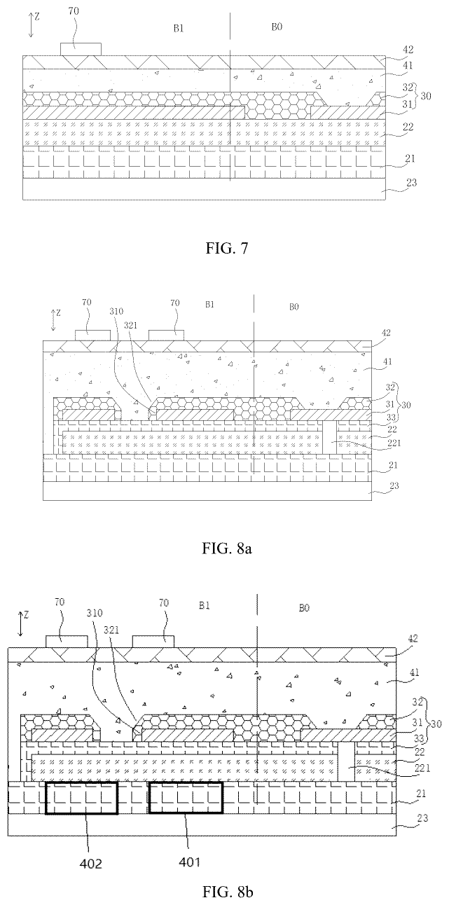

In a possible implementation, referring to FIG. 7, the display panel includes a display region B0 and a non-display region B1, where the non-display region B1 includes a first region B11. In the first region B11, a first organic layer 22 is isolated from the first encapsulation layer 41 by a structural function layer 30. The structural function layer 30 includes a first conductive layer 31 and a first inorganic layer 32 stacked along a thickness direction Z of the substrate. The first conductive layer 31 is continuous in the first region B11; and the first inorganic layer 32 is continuous in the first region B11, and an orthographic projection of the structural function layer 30 on the substrate 23 is continuous in the first region B11. For example, in the first region B11, the first conductive layer 31 continuously covers a plurality of cascaded shift registers. For example, an area of an orthogonal projection of the first conductive layer 31 on the substrate 23 in the first region B11 equals an area of the first region B11. Thus, in the first region B11 or the non-display region B1, the first encapsulation layer 41 and the first organic layer 22 can be isolated by the first conductive layer 31 and the first inorganic layer 32 without direct contact.

For example, neither the first conductive layer 31 nor the first inorganic layer 32 is provided with an opening in the first region.

In a possible implementation, referring to FIGS. 8a and 8b, the display panel includes a display region B0 and a non-display region B1, and the non-display region B1 includes a first region B11. In the first region B11, a first organic layer 22 is isolated from the first encapsulation layer 41 by a structural function layer 30. The structural function layer 30 includes an inorganic isolation layer 33, a first conductive layer 31, and a first inorganic layer 32 stacked along a thickness direction Z of the substrate 23. The first conductive layer 31 is provided with a first opening 310 in the first region B11, and the first inorganic layer 32 is provided with a second opening 321 in the first region B11. An orthographic projection of the first opening 310 on the substrate 23 overlaps with an orthographic projection of the second opening 321 on the substrate 23. An overlapping region of the orthographic projections of the first opening 310 and the second opening 321 on the substrate 23 is located within an orthographic projection of the inorganic isolation layer 33 on the substrate 23, and an orthographic projection of the structural function layer 30 on the substrate 23 is continuous in the first region B11. Thus, in the first region B11 or the non-display region B1, the first encapsulation layer 41 may be isolated from the first organic layer 22 by the inorganic isolation layer 33.

For example, the inorganic isolation layer 33 is located on a side, facing the substrate 23, of the first conductive layer 31 and the first inorganic layer 32.

In some other embodiments, the inorganic isolation layer 33 is located between the first conductive layer 31 and the first inorganic layer 32.

In some other embodiments, the inorganic isolation layer 33 is located on a side, facing away from the substrate 23, of the first conductive layer 31 and the first inorganic layer 32.

For example, the inorganic isolation layer 33 may be an inorganic insulation layer.

Herein, the inorganic isolation layer 33 may be distributed continuously in the first region B11. For example, the inorganic isolation layer 33 has no opening in the first region B11. For example, the inorganic isolation layer 33 continuously covers a plurality of cascaded shift registers in the first region B11, and an area of an orthogonal projection of the inorganic isolation layer 33 on the substrate 23 in the first region B11 equals an area of the first region B11. For example, the inorganic isolation layer 33 in the first region B11 continuously covers all shift registers from a first-stage shift register to a last-stage shift register in a corresponding gate drive circuit. For example, for each first region B11 in at least one first region B11, the inorganic isolation layer 33 continuously covers all shift registers from the first-stage shift register to the last-stage shift register in a corresponding scan circuit 401, and/or continuously covers all shift registers from the first-stage shift register to the last-stage shift register in a corresponding emission control circuit 402.

In an example, a material of the inorganic isolation layer 33 may include silicon oxide, or silicon nitride, or silicon oxide and silicon nitride. Thus, in the first region B11 or the non-display region B1, the first encapsulation layer 41 may be isolated from the first organic layer 22 by the inorganic isolation layer 33, avoiding direct contact between the first encapsulation layer 41 and the first organic layer 22.

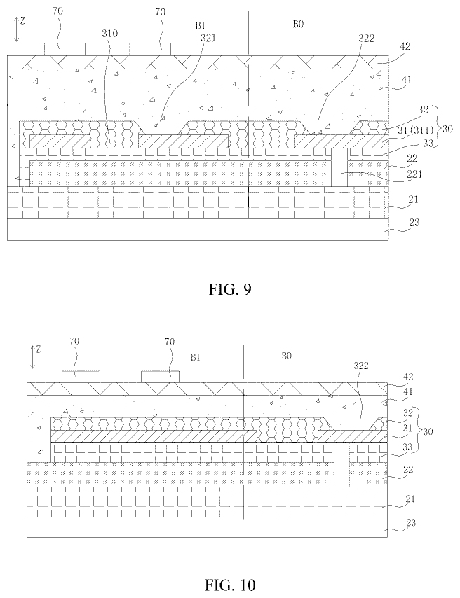

In a possible implementation, referring to FIG. 9, the display panel includes a display region B0 and a non-display region B1, and the non-display region B1 includes a first region B11. In the first region B11, a first organic layer 22 is isolated from the first encapsulation layer 41 by a structural function layer 30. The structural function layer 30 includes an inorganic isolation layer 33, a first conductive layer 31 and a first inorganic layer 32 stacked along a thickness direction Z of the substrate 23. The first conductive layer 31 is provided with a first opening 310 in the first region B11; and the first inorganic layer 32 is provided with a second opening 321 in the first region B11. An orthogonal projection of the first opening 310 on the substrate 23 is located outside an orthogonal projection of the second opening 321 on the substrate 23, and an orthogonal projection of the structural function layer 30 on the substrate 23 is continuous in the first region B11. That is, the first opening 310 and the second opening 321 are alternately distributed. In the first region B11 or the non-display region, the first encapsulation layer 41 may be isolated from the first organic layer 22 by the inorganic isolation layer 33, preventing direct contact between the first encapsulation layer 41 and the first organic layer 22. For example, the orthographic projection of the first opening 310 on the substrate 23 is located within an orthographic projection of the first inorganic layer 32 on the substrate 23. For example, the orthographic projection of the second opening 321 on the substrate 23 is located within the orthographic projection of the first conductive layer 31 on the substrate 23.

For example, the inorganic isolation layer 33 is located on a side, facing the substrate 23, of the first conductive layer 31 and the first inorganic layer 32.

For example, the inorganic isolation layer 33 may be an inorganic insulation layer.

Herein, the inorganic isolation layer 33 may be distributed continuously in the first region B11. For example, the inorganic isolation layer 33 has no opening in the first region B11. For example, the inorganic isolation layer 33 has no opening penetrating through the inorganic isolation layer 33 along the thickness direction of the substrate 23 in the first region B11. For example, in the first region B11 (i.e., the border region), the inorganic isolation layer 33 entirely or fully covers the first organic layer 22 entirely. In the first region B11 (i.e., the border region), the inorganic isolation layer 33 completely covers the first organic layer 22.

In a possible implementation, referring to FIG. 10, the display panel includes a display region B0 and a non-display region B1, and the non-display region B1 includes a first region B11. In the first region B11, a first organic layer 22 is isolated from a first encapsulation layer 41 by a structural function layer 30. The structural function layer 30 includes an inorganic isolation layer 33, a first conductive layer 31 and a first inorganic layer 32 stacked along a thickness direction Z of the substrate 23. The first conductive layer 31 is continuous in the first region B11, and the first inorganic layer 32 is continuous in the first region B11. The inorganic isolation layer 33 is continuous in the first region B11, and an orthographic projection of the structural function layer 30 on the substrate 23 is continuous in the first region B11. For example, in the first region B11, the first inorganic layer 32 continuously covers a plurality of cascaded shift registers. For example, an area of an orthographic projection of the inorganic isolation layer 33 on the substrate 23 in the first region B11 equals an area of the first region B11. For example, all of the first conductive layer 31, the first inorganic layer 32, and the inorganic isolation layer 33 have no opening in the first region B11.

Thus, in the first region B11 or the non-display region B1, the first encapsulation layer 41 may be isolated from the first organic layer 22 by the inorganic isolation layer 33, avoiding direct contact between the first encapsulation layer 41 and the first organic layer 22.

For example, the inorganic isolation layer 33 is located on a side, facing the substrate 23, of the first conductive layer 31 and the first inorganic layer 32.

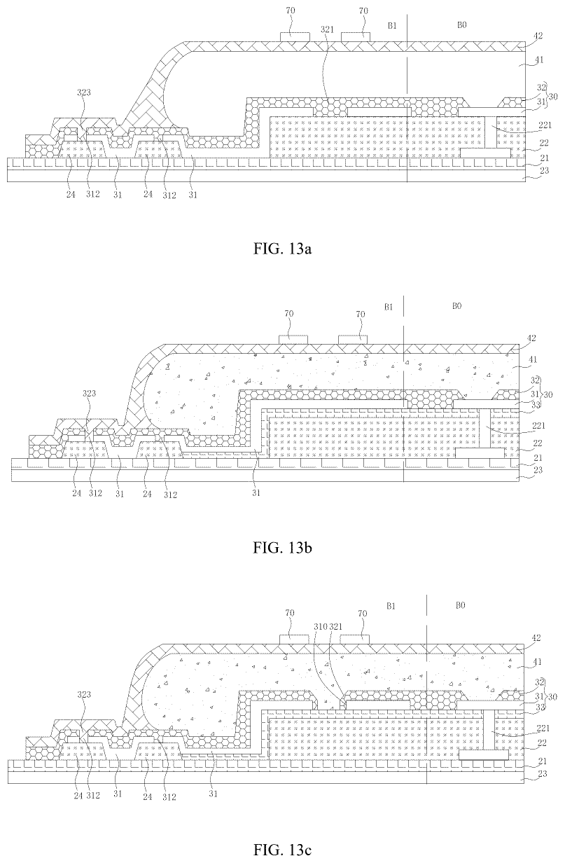

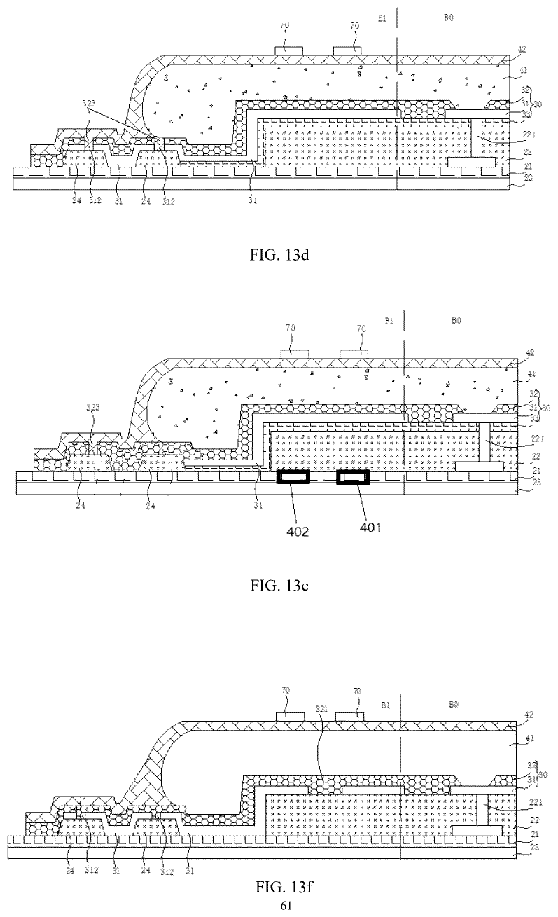

For example, referring to FIG. 13b, in the first region B11, a boundary of an inorganic isolation layer 33 away from the display region B0 is located on a side, away from the display region B0, of a boundary of the first organic layer 22, where the boundary of the first organic layer 22 is a boundary, away from the display region B0, of the first organic layer 22.

For example, the inorganic isolation layer 33 may be an inorganic insulation layer. For example, the first inorganic layer 32 is an inorganic insulation layer.

In a possible implementation, referring to FIG. 10, the display panel further includes a signal wiring line 70 located in the first region, and the signal wiring line 70 is disposed on a side, facing away from the substrate 23, of the second encapsulation layer 42. Thus, the driving circuit layer 21 and the signal wiring line 70 are located on opposite sides of the first conductive layer 31 along a direction parallel to a thickness direction Z of the substrate 23. The first conductive layer 31 may function as a signal shield, reducing mutual interference between the signal wiring line 70 and the driving circuit layer 21.

The drive circuit layer 21 includes a gate drive circuit. In the first region B11, the gate drive circuit and the signal wiring line 70 are located on opposite sides of the first conductive layer 31 along the direction parallel to the thickness direction Z of the substrate 23. The first conductive layer 31 may function as a signal shield, reducing mutual interference between the signal wiring line 70 and the gate drive circuit.

For example, the signal wiring line 70 is a touch wiring line. For example, the display panel may further include a touch electrode (not shown in figures.), which may be located in the display region B0 and electrically connected to the touch wiring line (e.g., the signal wiring line 70) to implement touch functionality.

The first region B11 may include a border region located on at least one side of the display region B0. In one embodiment, the first region B11 may include a first border region and a second border region located on opposite sides of the display region B0.

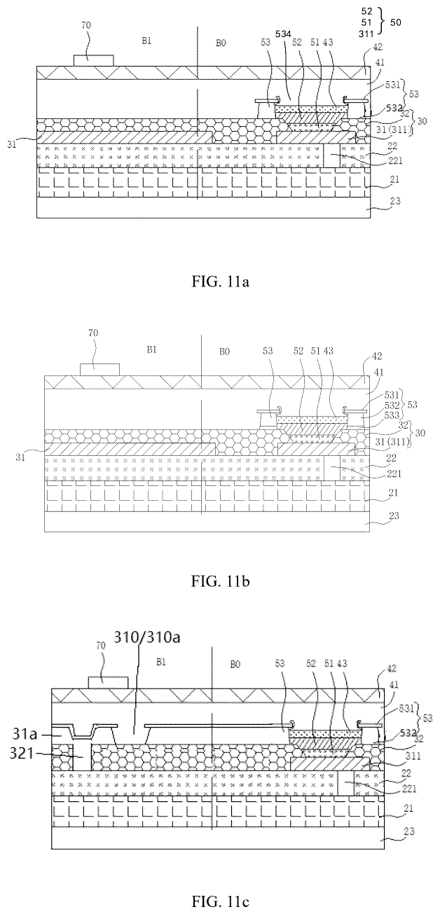

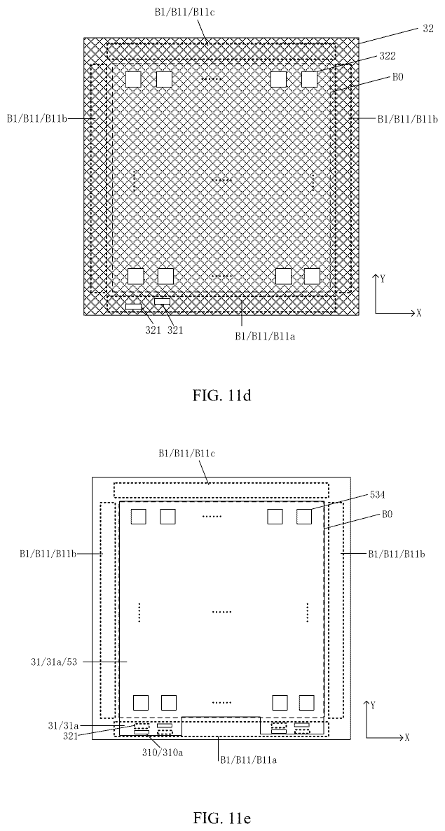

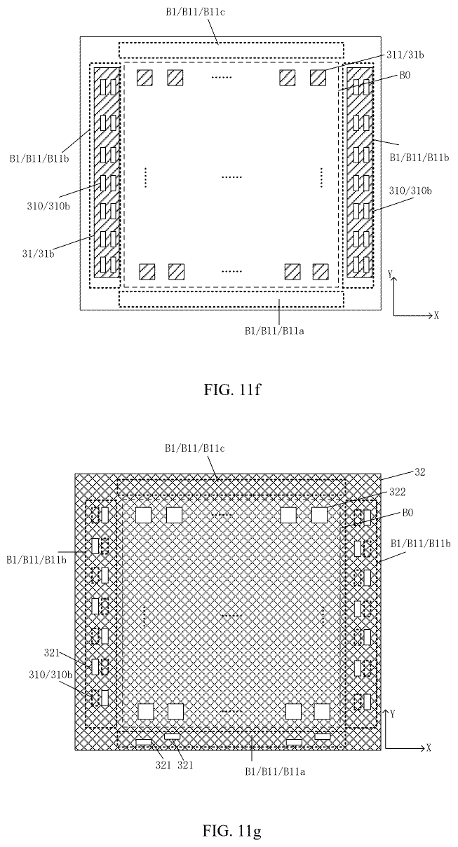

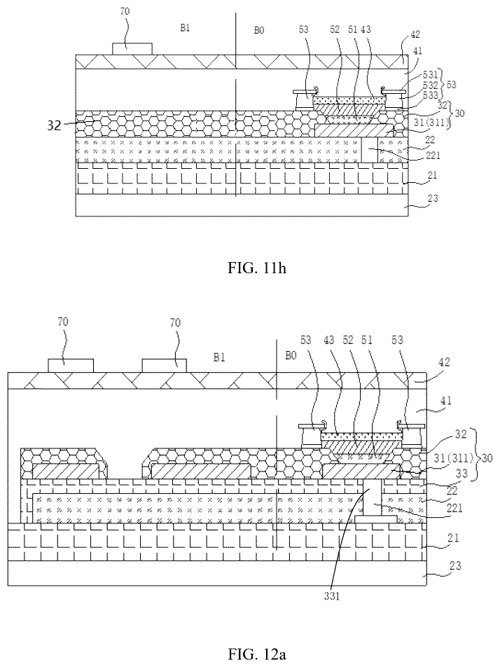

The first conductive layer 31 is located between the first inorganic layer 32 and the substrate 23. In one embodiment, the first inorganic layer 32 is located between the first conductive layer 31 and the substrate 23. In a possible embodiment, referring to FIG. 11a or FIG. 11b, the first conductive layer 31 is located between the first inorganic layer 32 and the substrate 23. The first organic layer 22 is provided with a via hole 221 in the display region B0. A drive circuit layer 21 includes a pixel circuit located in the display region B0. The first conductive layer 31 includes a first electrode portion 311 in the display region B0, and the first electrode portion 311 is electrically connected to the pixel circuit through the via hole 221. Thus, it can be understood that the first conductive layer 31 and the first inorganic layer 32 are sequentially stacked along a direction away from the substrate 23. The pixel circuit in the drive circuit layer 21 can provide a drive current to the first electrode portion 311, that is, provide a drive current to a light-emitting device.

In a possible embodiment, referring to FIG. 11a or FIG. 11b, the first inorganic layer 32 is a pixel defining layer. For example, the display panel may further include a light-emitting device. The light-emitting device 50 includes a first electrode portion 311, a light-emitting structure 51, and a second electrode portion 52 sequentially stacked along a direction Z away from the substrate 23. The first electrode portion 311 is located between the first inorganic layer 32 and the substrate 23. The first inorganic layer 32 is provided with a pixel opening 322 in the display region B0. At least part of a surface, facing away from the substrate 23, of the first electrode portion 311 is exposed by the pixel opening 322. The light-emitting structure is stacked on the surface, away from the substrate 23, of the first electrode portion 311 through the pixel opening 322. Thus, the first electrode portion 311, the light-emitting structure 51, and the second electrode portion 52 can form a light-emitting unit. The driving circuit layer 21 may control the light-emitting unit to emit light through an electrical connection with the first electrode portion 311. For example, one of the first electrode portion 311 and the second electrode portion 52 is an anode, and the other is a cathode. For example, the first electrode portion 311 is an anode, and the second electrode portion 52 is a cathode.

In an example, the first electrode portion 311 is located in the first conductive layer 31. The first electrode portion 311 is electrically connected to a pixel circuit in the driving circuit layer 21 through the via hole 221 in the first organic layer 22.

In a possible embodiment, referring to FIG. 11a or FIG. 11b, the display panel may further include an isolation structure 53. The isolation structure 53 may be located between the first organic layer 22 and the first encapsulation layer 41. A plurality of isolation openings 534 are defined by the isolation structure 53. The isolation structure 53 may be located on a side, away from the substrate 23, of the pixel defining layer or the first inorganic layer 32. In one embodiment, the pixel defining layer or the first inorganic layer 32 is provided with a recessed opening, and the isolation structure 53 may be located in the recessed opening. The pixel defining layer may include a pixel defining portion, and a plurality of pixel openings may be defined by the pixel defining portion.

For example, the display panel may further include a plurality of light-emitting devices 50. the plurality of light-emitting devices 50 may be located between the first organic layer 22 and the first encapsulation layer 41. At least part of a light-emitting device 50 is located in a corresponding isolation opening 534. The light-emitting device 50 includes a first electrode portion 311, a light-emitting structure 51, and a second electrode portion 52 sequentially stacked along the direction away from the substrate 23, and the second electrode portion 52 is electrically connected to the isolation structure 53. For example, a material of the isolation structure 53 includes a conductive material. Thus, adjacent light-emitting devices 50 may be isolated reliably by the isolation structure 53, and second electrode portions 52 of adjacent light-emitting devices 50 may be connected by the isolation structure 53, thereby ensuring conductive uniformity of the second electrode portions 52.

In an example, the isolation structure 53 is disposed on a side, away from the substrate 23, of the first inorganic layer 32. The first inorganic layer 32 is a pixel defining layer, and the first inorganic layer 32 is provided with a plurality of pixel openings 322 in the display region B0, where the plurality of pixel openings 322 are arranged in correspondence with the plurality of isolation openings 534. For example, a pixel opening 322 communicates with an isolation openings 534 correspondingly. An orthographic projection of the pixel opening 322 on the substrate 23 is located within an orthographic projection of the isolation opening 534 on the substrate 23. For example, at least part of a surface, facing away from the substrate 23, of the first electrode portion 311 is exposed by the pixel opening 322.

In an example, the display panel may further include a plurality of encapsulation portions 43. An encapsulation portion 43 is located on a side, facing away from the substrate 23, of a corresponding light-emitting device 50, and are positioned between the first encapsulation layer 41 and a film layer where the light-emitting devices 50 are located. Thus, moisture and oxygen may be blocked by the encapsulation portion 43, and the light-emitting device 50 may be protected. A material of the encapsulation portion 43 may include an inorganic material, such as an inorganic insulating material. For example, the plurality of encapsulation portions 43 may be arranged at intervals.

The plurality of light-emitting devices 50 can be of various types, and the different types are used to emit light of different colors. For example, light-emitting devices 50 of different emission colors correspond to different encapsulation portions 43.

For example, at least part of the first conductive layer 31 (e.g., the first conductive layer 31 may include a first sub-conductive layer) is arranged in the same layer as at least part of the isolation structure 53, or at least part of the first conductive layer 31 (e.g., the first conductive layer 31 may include a second sub-conductive layer) is arranged in the same layer as the first electrode portion 311 of the light-emitting device 50; or a part of the first conductive layer 31 is arranged in the same layer as at least part of the isolation structure 53 and another part of the first conductive layer 31 is arranged in the same layer as the first electrode portion 311 of the light-emitting device 50.

For example, in at least one first region B11 (e.g., including a lower border region), the first organic layer 22 and the first encapsulation layer 41 are isolated by the first inorganic layer 31 in the structural function layer 30 and the first sub-conductive layer.

For example, in at least one first region B11 (e.g., including the left border region, or the right border region, or the left border region and the right border region), the first organic layer 22 and the first encapsulation layer 41 are isolated by the first inorganic layer 31 and the second sub-conductive layer in the structural function layer 30.

For example, the inorganic isolation layer 33 may be arranged in the same layer as the encapsulation portion 43, for example, with the same material.

Referring to FIG. 11a, the isolation structure 53 includes a first structural layer 531 and a second structural layer 532. The first structural layer 531 and the second structural layer 532 are sequentially stacked along a direction toward the substrate 23. A sidewall, facing an isolation opening 534, of the first structural layer 531 protrudes beyond a sidewall, facing the isolation opening 534, of the second structural layer 532. For example, an orthographic projection of a side, facing away from the substrate 23, of the second structural layer 532 on the substrate 23 is located within an orthographic projection of the first structural layer 531 on the substrate 23. For example, an area of the orthographic projection area of the side, facing away from the substrate 23, of the second structural layer 532 on the substrate 23 is smaller than an area of the orthographic projection of the first structural layer 531 on the substrate 23. For example, a shape of a cross-section of the isolation structure 53 perpendicular to the substrate 23 may be T-shape. For example, a material of the first structural layer 531 is different from a material of the second structural layer 532. For example, the material of the second structural layer 532 includes a conductive material. For example, the second electrode portion 52 and the second structural layer 532 are in conductive contact. For example, the material of the first structural layer 531 includes a conductive material, such as a metal material, for example, titanium metal, and/or the material of the second structural layer 532 includes a conductive material, such as a metal material, for example, aluminum metal.

For example, referring to FIG. 11B, the isolation structure further includes a third structural layer 533. The first structural layer 531, the second structural layer 532, and the third structural layer 533 are sequentially stacked along the direction toward the substrate 23. The orthographic projection of the second structural layer 532 on the substrate 23 is located within an orthographic projection of the third structural layer 533 on the substrate 23. For example, the area the orthographic projection of the second structural layer 532 on the substrate 23 is smaller than an area of the orthographic projection of the third structural layer 533 on the substrate 23. For example, a shape of a cross-section of the isolation structure 53 perpendicular to the substrate 23 may be I-shape. For example, a material of the third structural layer 533 may be the same as or different from the material of the first structural layer 531. For example, the material of the third structural layer 533 includes a conductive material, such as a metal material, for example, molybdenum.

In a possible implementation, referring to FIGS. 4A, 4B, 5, 11C, 11D, 11E, 11F, and 11G, the display panel includes a display region B0 and a non-display region B1. The non-display region B1 includes a plurality of first regions B11. In the plurality of first regions B11, a first organic layer 22 is isolated from a first encapsulation layer 41 by a structural function layer 30. The structural function layer 30 includes a first conductive layer 31 and a first inorganic layer 32 stacked along a thickness direction Z of the substrate 23. The first conductive layer 31 includes a first sub-conductive layer 31a and a second sub-conductive layer 31b.

For example, the first sub-conductive layer 31a and the second sub-conductive layer 31b are located in different conductive layers. For example, one of the first sub-conductive layer 31a and the second sub-conductive layer 31b is located on a side, away from the substrate 23, of the first inorganic layer 32, and the other is located on a side, facing the substrate 23, of the first inorganic layer 32. For example, the first inorganic layer 32 is located between the first sub-conductive layer 31a and the second sub-conductive layer 31b.

The plurality of first regions B11 include a first-type first region B11a, or a second-type first region B11b, or the first-type first region B11a and the second-type first region B11b.

Referring to FIG. 11c, FIG. 11d, and FIG. 11e, in the first-type first region B11a: the first sub-conductive layer 31a is provided with a first opening 310a in the first-type first region B11a; the first inorganic layer 32 is provided with a second opening 321 in the first-type first region B11a; an orthographic projection of the first opening 310a on the substrate 23 is located outside an orthographic projection of the second opening 321 on the substrate 23, that is, the orthographic projection of the first opening 310a and the orthographic projection of the second opening 321 do not overlap and are arranged in a staggered manner. The orthographic projection of the first opening 310a on the substrate 23 is located within an orthographic projection of the first inorganic layer 32 on the substrate 23. The orthographic projection of the second opening 321 on the substrate 23 is located within an orthographic projection of the first sub-conductive layer 31a on the substrate 23. This configuration enables the orthographic projection of the structural function layer 30, in the first-type first region B11a, on the substrate 23 is continuous. In the first-type first region B11a, the first organic layer 22 and the first encapsulation layer 41 are isolated by the first sub-conductive layer 31a and the first inorganic layer 32. For example, in the first-type first region B11a, the first sub-conductive layer 31a and the first inorganic layer 32 are stacked along a thickness direction Z of the substrate 23. The first sub-conductive layer 31a can be connected to a power signal line through the second opening 321.

Referring to FIG. 4a, FIG. 4b, FIG. 11f, and FIG. 11g, in the second-type first region B11b: the second sub-conductive layer 31b is provided with a first opening 310b in the second-type first region B11b, and the first inorganic layer 32 is provided with a second opening 321 in the second-type first region B11b. An orthographic projection of the first opening 310b on the substrate 23 is located outside an orthographic projection of the second opening 321 on the substrate 23, that is, the orthographic projection of the first opening 310b and the orthographic projection of the second opening 321 do not overlap and are arranged in a staggered manner. The orthographic projection of the first opening 310b on the substrate 23 is located within an orthographic projection of the first inorganic layer 32 on the substrate 23. The orthographic projection of the second opening 321 on the substrate 23 is located within an orthographic projection of the second sub-conductive layer 31b on the substrate 23. This configuration enables the orthographic projection of the structural function layer 30, in the second-type first region B11b, on the substrate 23 is continuous. In the second-type first region B11b, the first organic layer 22 and the first encapsulation layer 41 are isolated by the second sub-conductive layer 31b and the first inorganic layer 32. For example, in the second-type first region B11b, the second sub-conductive layer 31b and the first inorganic layer 32 are stacked along a thickness direction Z of the substrate 23.

In one embodiment, referring to FIGS. 5, 11d, and 11f, in the second-type first region B11b, the second sub-conductive layer 31b is provided with a first opening 310b in the second-type first region B11b, and the first inorganic layer 32 is continuous in the second-type first region B11b. An orthographic projection of the first opening 310b on the substrate 23 is located within an orthographic projection of the first inorganic layer 32 on the substrate 23. The first inorganic layer 32 has no opening in the second-type first region B11b. This configuration enables that the orthographic projection of the structural function layer 30 in the second-type first region B11b on the substrate 23 is continuous. In the second-type first region B11b, the first organic layer 22 and the first encapsulation layer 41 are isolated by the second sub-conductive layer 31b and the first inorganic layer 32. For example, in the second-type first region B11b, the second sub-conductive layer 31b and the first inorganic layer 32 are stacked along a thickness direction Z of the substrate 23.

For example, the first sub-conductive layer 31a is arranged in the same layer as the isolation structure 53, or the first sub-conductive layer 31a includes at least part of the isolation structure 53.

For example, the second sub-conductive layer 31b is arranged in the same layer as the first electrode portion 311 of the light-emitting device 50, or the second sub-conductive layer 31b includes the first electrode portion 311.

For example, the first inorganic layer 32 is a pixel defining layer.

For example, the first-type first region B11a and the second-type first region B11b are located in adjacent border regions on at least two sides of the display region (e.g., the bottom border region and the left border region).

For example, the first-type first region B11a may include the bottom border region or be located in the bottom border region. For example, the first-type first region B11a is located on a same side as the driver chip in the display region.

For example, the second-type first region B11a may include a left border region or a right border region, or be located in the left border region or right border region. For example, the second-type first region B11a is provided with a gate driver circuit.

For example, no isolation structure 53 is provided in the second-type first region B11a.

For example, a material of the first sub-conductive layer 31a includes a metal material. For example, a material of the second sub-conductive layer 31b includes a metal material.

For example, the plurality of first regions B11 may further include a third-type first region B11c. Referring to FIGS. 11d, 11e, 11f, and 11h, in the third-type first region B11c, the first inorganic layer 32 is continuous in the third-type first region B11c. This configuration enables the orthographic projection of the structural function layer 30, in the third-type first region B11c, on the substrate 23 is continuous. In the third-type first region B11c, the first organic layer 22 is isolated from the first encapsulation layer 41 by the first inorganic layer 32. For example, no isolation structure 53 is provided in the third-type first region B11c. For example, no first conductive layer 31 is provided in the third-type first region B11c. For example, no first sub-conductive layer 31a is provided in the third-type first region B11c. For example, no second sub-conductive layer 31b is provided in the third-type first region B11c.

For example, the third-type first region B11c may include or be located in the bottom border region.

In some other possible embodiments, the first conductive layer 31 includes one of the first sub-conductive layer 31a and the second sub-conductive layer 31b.

In some other possible embodiments, the first region B11 includes one or more of the first-type first region B11a, the second-type first region B11b, and the third-type first region B11c.

In some other possible embodiments, the structural function layer 30 of the second-type first region B11b, the left border region, or the right border region may be as shown in FIGS. 4a to 11b, 12a to 13f.

In some other possible embodiments, the structural function layer 30 of the first-type first region B11a or the bottom border region may be as shown in FIGS. 4a to 11b, 12a to 13f.

In some other possible embodiments, the structural function layer 30 of the third-type first region B11c or the top border region may be as shown in FIGS. 4a to 11b, 12a to 13f.

For example, at least one border region (e.g., the bottom border region) includes two or three of the first-type first region B11a, the second-type first region B11b, and the third-type first region B11c. For example, the bottom border region may include the first-type first region B11a and the second-type first region B11b.

For example, the left border region or the right border region may include two or three of the first-type first region B11a, the second-type first region B11b, and the third-type first region B11c.

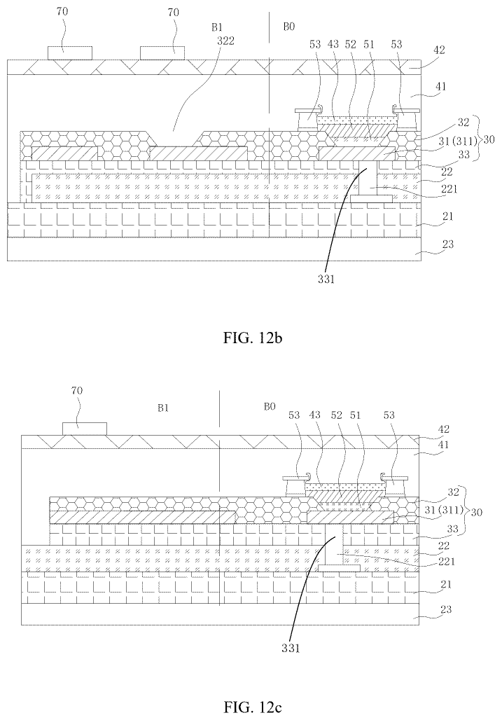

In another possible embodiment, referring to FIG. 12a, FIG. 12b, or FIG. 12c, a first conductive layer 31 is located between a first inorganic layer 32 and a substrate 23. A first organic layer 22 is provided with a via hole 221 in the display region B0, and the inorganic isolation layer 33 is provided with a third opening 331 in the display region B0. An orthographic projection of the via hole 221 on the substrate 23 overlaps with an orthographic projection of the third opening 331 on the substrate 23. The first conductive layer 31 includes a first electrode portion 311 in the display region B0, and the first electrode portion 311 is electrically connected to the drive circuit layer 21 through the third opening 331 and the via hole 221. Thus, the orthographic projection of the third opening 331 on the substrate 23 is located within an orthographic projection of the first electrode portion 311 on the substrate 23, and the drive circuit layer 21 is configured to supply power to the first electrode portion 311.

For example, the first inorganic layer 32 is located between the first conductive layer 31 and the substrate 23. For example, at least part of the first conductive layer 31 may be arranged in the same layer as the second electrode portion 52, or at least part of the first conductive layer 31 may be arranged in the same layer as at least part of the isolation structure 53, or a part of the first conductive layer 31 may be arranged in the same layer as the second electrode portion 52 and another part of the first conductive layer 31 may be arranged in the same layer as at least part of the isolation structure 53. Two structures arranged in the same layer can be obtained by patterning the same film layer to simplify the process.

In a possible implementation, referring to FIG. 13a, FIG. 13b, or FIG. 13c, the display panel may further include a bank 24 located in the non-display region B1 of the display panel. For example, the first region B11 is located between the bank 24 and the display region B0.

The first encapsulation layer 41 is located on a side, closer to the display region B0, of at least part of the bank 24. A material of the bank 24 includes an organic material. The first conductive layer 31 is disposed on a side, facing away from the substrate 23, of the bank 24. The first conductive layer 31 is provided with a first via hole 312, and an orthographic projection of the bank 24 on the substrate 23 overlaps with an orthographic projection of the first through hole 312 on the substrate 23. Thus, a portion of a surface of a side, facing away from the substrate 23, of the bank 24 may be exposed by the first via hole 312. Thus, during the manufacturing process, moisture in the bank 24 can be released through the first via hole 312. The bank 24 can be used to prevent overflow of organic material during the preparation of the first encapsulation layer 41, which is beneficial for achieving a narrow border.

In an example, the first inorganic layer 32 is provided with a second via hole 323, and an overlapping region between the orthographic projection of the first via hole 312 on the substrate 23 and an orthographic projection of the second via hole 323 on the substrate 23 overlaps with the orthographic projection of the bank 24 on the substrate 23. Thus, the first via hole 312 and the second via hole 323 are in communication, or the first via hole 312 and the second via hole 323 form a nested via hole. Thus, during the manufacturing process, moisture in the bank 24 may be released through the first via hole 312 and the second via hole 323.

The bank 24 may include a plurality of units. For example, the bank 24 may include two units. For example, an overlapping region between the orthographic projection of at least one first via hole 312 on the substrate 23 and the orthographic projection of at least one second via hole 323 on the substrate 23 overlaps with an orthographic projection of a unit of the bank 24 located away from the display region B0 on the substrate 23, as shown in FIG. 13b. For example, the orthographic projection of at least one first via hole 312 on the substrate 23 overlaps with an orthographic projection of a unit of the bank 24 located closer the display region B0 on the substrate 23, as shown in FIG. 13b. For example, the first inorganic layer 32 may fill the first via hole 312 and contact the unit of the bank 24 located closer the display region B0.

For example, the material of the bank 24 is the same as the material of the first organic layer 22.

The bank 24 may include a plurality of units. For example, the bank 24 may include two units. For example, the overlapping region between the orthographic projection of at least one first via hole 312 on the substrate 23 and the orthographic projection of at least one second via hole 323 on the substrate 23 overlaps with the orthographic projection of a unit, away from the display region B0, of the bank 24 located on the substrate 23, as shown in FIG. 13d. For example, the overlapping region between the orthographic projection of at least one first via hole 312 on the substrate 23 and the orthographic projection of at least one second via hole 323 on the substrate 23 overlaps with the orthographic projection of a unit, closer to the display region B0, of the bank 24 located on the substrate 23, as shown in FIG. 13d. For example, the first via hole 312 and the second via hole 323 may be filled with the second encapsulation layer 42, and the second encapsulation layer 42 is in contact with the bank 24.

In another possible implementation, referring to FIG. 13e, the display panel may further include a bank 24 located in the non-display region B1. The first encapsulation layer 41 is located on the side, closer to the display region B0, of at least part of the bank 24. The material of the bank 24 includes an organic material.

The inorganic isolation layer 33 is located on a side, closer to the display region B0, of the bank 24, and the first conductive layer 31 is located on the side, closer to the display region B0, of the bank 24. The first inorganic layer 32 is provided with a second via hole 323, and an orthographic projection of the bank 24 on the substrate 23 overlaps with an orthographic projection of the second via hole 323 on the substrate 23. Thus, during the manufacturing process, moisture in the bank 24 may be released through the second via hole 323. The bank 24 may include a plurality of units. For example, the bank 24 may include two units. For example, an orthographic projection of a unit, away from the display region, of the bank 24 on the substrate 23 overlaps with the orthographic projection of the second via hole 323 on the substrate. For example, an orthographic projection of a unit, closer to the display region, of the bank 24 on the substrate 23 does not overlap with the orthographic projection of the second via hole 323 on the substrate.

For example, the bank 24 and the isolation layer 33 are spaced apart.

In another possible implementation, referring to FIG. 13e, in the region where the bank 24 is located, the first inorganic layer 32 is continuous without via holes.

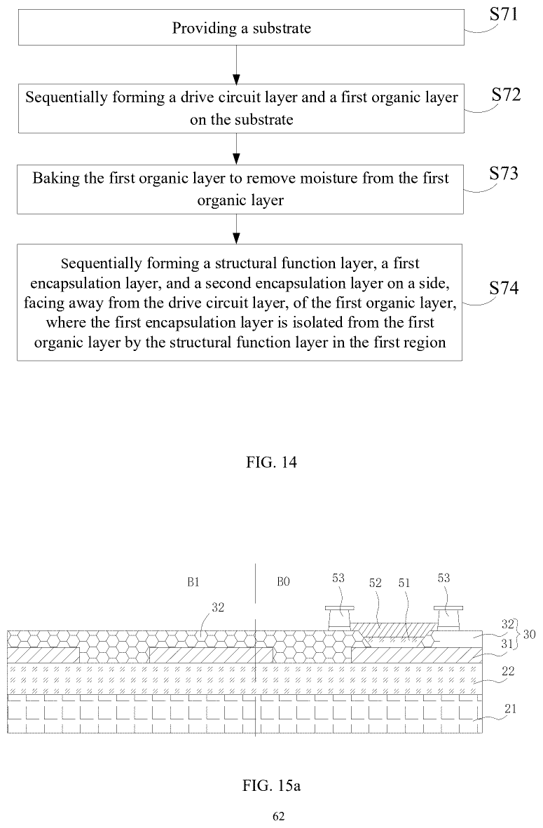

The present disclosure further provides a manufacturing method for a display panel, which can be used to prepare the display panel mentioned in the above embodiments. Referring to FIG. 14 and FIG. 4b, the manufacturing method includes the following steps.

Step S71: providing a substrate.

Step S72: sequentially forming a drive circuit layer and a first organic layer on the substrate.

Step S73: baking the first organic layer to remove moisture from the first organic layer.

Step S74: sequentially forming a structural function layer, a first encapsulation layer, and a second encapsulation layer on a side, facing away from the drive circuit layer, of the first organic layer, where the first encapsulation layer is isolated from the first organic layer by the structural function layer in the first region.

In one embodiment, in the display panel obtained by the above manufacturing method, through the isolation of the structural function layer 30, direct contact between the first encapsulation layer 41 and the first organic layer 22 can be avoided. Even if the second encapsulation layer 42 is damaged, external moisture will be blocked by the structural function layer 30, making it difficult to enter the first organic layer 22 from the first encapsulation layer 41, thereby preventing moisture from invading the drive circuit layer 21 from the first organic layer 22. Thus, moisture may be prevented from entering a damaged area of the second encapsulation layer 42 to corrode the drive circuit layer 21, thus solving a problem of display abnormalities in the display panel. Additionally, by baking to remove moisture from the first organic layer 22 before forming the structural function layer 30, it can also prevent moisture in the first organic layer 22 from corroding the drive circuit layer 21. After forming the structural function layer 30, during subsequent high-temperature processes (such as in the preparation of light-emitting devices), if there is little or no moisture in the first organic layer 22, there is no need to set vent holes in the structural function layer 30 to release moisture generated by the first organic layer 22. For example, in step S73, the substrate with the first organic layer 22 formed thereon can be baked, thereby baking the substrate and various film layers located thereon to remove moisture from the substrate and the various film layers.

This embodiment can be combined with some or all features of the above embodiments, which will not be repeated herein again.

In a possible implementation, referring to FIGS. 4a to 7 and FIG. 18, the step of forming the structural function layer on the side, facing away from the drive circuit layer, of the first organic layer in one embodiment includes the following steps.

Step S7411: forming a first conductive layer on a side, facing away from the drive circuit layer, of the first organic layer; and

Step S7412: forming a first inorganic layer on a side, facing away from the drive circuit layer, of the first conductive layer.

The display panel includes a display region B0 and a non-display region B1, and the non-display region B1 includes a first region B11. The first conductive layer 31 is provided with a first opening 310 in the first region B11, and the first inorganic layer 32 is provided with a second opening 321 in the first region B11. An orthographic projection of the first opening 310 on the substrate 23 is located outside an orthographic projection of the second opening 321 on the substrate 23.

In one embodiment, the first conductive layer 31 is provided with the first opening 310 in the first region B11, and the first inorganic layer 32 is continuous in the first region B11. The orthographic projection of the first opening 310 on the substrate 23 is located within an orthographic projection of the first inorganic layer 32 on the substrate 23.

In one embodiment, the first conductive layer 31 is continuous in the first region B11, and the first inorganic layer 32 is provided with the second opening 321 in the first region B11. The orthographic projection of the second opening 321 on the substrate 23 is located within an orthographic projection of the first conductive layer 31 on the substrate 23.

In one embodiment, the first conductive layer 31 is continuous in the first region B11, and the first inorganic layer 32 is continuous in the first region B11.

Based on the above manufacturing method, in one embodiment, the structural function layer 30 includes the first conductive layer 31 and the first inorganic layer 32, and the first encapsulation layer 41 is isolated from the first organic layer 22 by the first conductive layer 31 and the first inorganic layer 32 jointly, avoiding direct contact between the first encapsulation layer 41 and the first organic layer 22.

After forming the first inorganic layer 32 and before forming the first encapsulation layer 41, referring to FIG. 15a or FIG. 15b, and FIG. 18, the manufacturing method provided in the present disclosure further includes the following steps.

Step S7413: forming an isolation structure, where an isolation opening is defined by the isolation structure.

Step S7414: patterning the first inorganic layer to form a pixel opening, where an orthographic projection of the pixel opening on the substrate is located within an orthographic projection of the isolation opening on the substrate, and at least part of a surface, facing away from the substrate, of the first conductive layer is exposed in the pixel opening.

Step S7415: sequentially forming a light-emitting structure and a second electrode portion, where the light-emitting structure is disposed in the pixel opening, and the light-emitting structure and the second electrode portion are sequentially stacked on a side, facing away from the drive circuit layer, of the first conductive layer along a direction away from the drive circuit layer.

Thus, after forming the light-emitting structure 51, the second electrode portion 52, and the encapsulation portion 43, the first encapsulation layer 41 and the second encapsulation layer 42 can be sequentially formed, and the first encapsulation layer 41 is isolated from the first organic layer 22 by the structural function layer 30.

Referring to FIG. 15b, the manufacturing method provided in the present disclosure further includes: forming a via hole in the first organic layer located in the display region, to allow the first electrode portion of the first conductive layer located in the display region to be electrically connected to the drive circuit layer through the via hole. Thus, a light-emitting device 50 is formed by the first electrode portion 311, the light-emitting structure 51, and the second electrode portion 52.

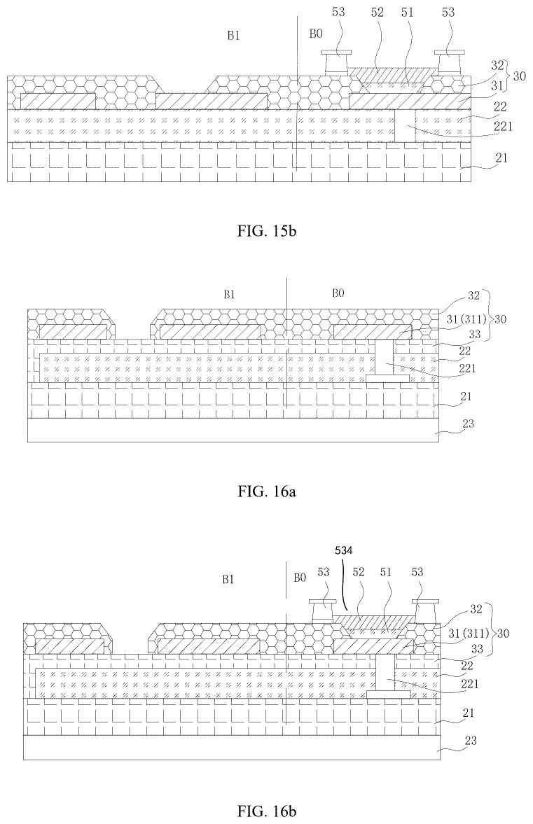

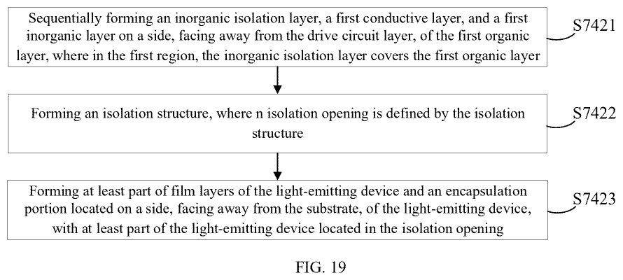

In another possible implementation, referring to FIG. 16a and FIG. 19, the step of forming the structural function layer on the side, facing away from the drive circuit layer, of the first organic layer includes the following steps.

Step S7421: sequentially forming an inorganic isolation layer, a first conductive layer, and a first inorganic layer on a side, facing away from the drive circuit layer, of the first organic layer, where in the first region, the inorganic isolation layer covers the first organic layer.

Thus, the first encapsulation layer 41 may be isolated from the first organic layer 22 by the inorganic isolation layer 33, avoiding direct contact between the first encapsulation layer 41 and the first organic layer 22. A material of the inorganic isolation layer 33 may include an inorganic insulating material.

Based on this method, in the first region B11, the first encapsulation layer 41 may be isolated from the first organic layer 22 by the inorganic isolation layer 33, avoiding direct contact between the first encapsulation layer 41 and the first organic layer 22.

In an example, the inorganic isolation layer 33 is continuous in the first region B11.

The first conductive layer 31 includes a first electrode portion 311 in the display region B0. The first organic layer 22 located in the display region B0 is provided with a via hole 221. The inorganic isolation layer 33 is provided with a third opening 331 communicating with the via hole 221. The first electrode portion is electrically connected to the driving circuit layer in the first organic layer 22 through the third opening 331 and the via hole 221.

After forming the structural function layer 30 and before forming the first encapsulation layer 41, referring to FIG. 16b and FIG. 19, the manufacturing method provided in the present disclosure further includes the following steps.

Step S7422: forming an isolation structure, where an isolation opening is defined by the isolation structure.

Step S7423: forming at least part of film layers of the light-emitting device and an encapsulation portion located on a side, facing away from the substrate, of the light-emitting device, with at least part of the light-emitting device located in the isolation opening.

The at least part of the film layers of the light-emitting device 50 may include a light-emitting structure 51 and a second electrode portion 52. Before forming the isolation structure 53 and the first inorganic layer 32, the first electrode portion 311 is formed.

In an example, the first conductive layer 31 includes the first electrode portion 311 in the display region B0. The light-emitting device 50 includes the first electrode portion 311, the light-emitting structure 51, and the second electrode portion 52. After forming the isolation opening 534, the first inorganic layer 32 is patterned to form a pixel opening 322. An orthographic projection of the pixel opening 322 on the substrate 23 is within an orthographic projection of the isolation opening 534 on the substrate 23. Part of a surface, facing away from the substrate 23, of the first electrode portion 311 is exposed in the pixel opening 322. Then, the light-emitting structure 51 and the second electrode portion 52 are sequentially formed. At least part of the light-emitting structure 51 is disposed in the pixel opening 322, and the light-emitting structure 51 and the second electrode portion 52 are sequentially stacked on a side, facing away from the driving circuit layer 21, of the first electrode portion 311. The first encapsulation layer 41 is located on a side, facing away from the driving circuit layer 21, of the second electrode portion 52. The second electrode portion 52 is at least partially located in the isolation opening 534 and overlaps with the isolation structure 53. Thus, the isolation structure 53 can reliably disconnect adjacent light-emitting structures 51, and an overlapping region between the second electrode portion 52 and the isolation structure 53 is beneficial for structural stability. Moreover, after forming the light-emitting structure 51, the second electrode portion 52 and the encapsulation portion, the first encapsulation layer 41 and the second encapsulation layer 42 can be sequentially formed. The first encapsulation layer 41 is isolated from the first organic layer 22 by the structural function layer 30.

The light-emitting structure 51 may include one or more of: a Hole Injection Layer (HIL), a Hole Transport Layer (HTL), an Emitting Layer (EML), and an Electron Transport Layer (ETL). Organic light-emitting materials in the light-emitting layer generally include: high molecular weight polymer, small molecule organic compound, and complex light-emitting materials. The high molecular weight polymer is usually conductive conjugated polymer or semiconductor conjugated polymer, which can be formed into films by spin-coating methods, with simple manufacturing process and low cost. However, their purity is not high, and they are inferior to small molecule organic compound in terms of durability, brightness, and color. A small molecule organic light-emitting material is mainly an organic dye, which have advantages of strong chemical modifiability, wide selection range, easy purification, high quantum efficiency, and can produce various color emission peaks such as red, green, blue, and yellow. However, most of them suffer from concentration quenching and other issues in the solid state. Complex light-emitting materials are between organic and inorganic substances, possessing both the high fluorescence quantum efficiency of organic materials and the high stability of inorganic materials, and are considered a promising class of light-emitting materials.

The encapsulation portion 43 is not shown in FIGS. 15a, 15b, 16a, and 16b. The structure of the encapsulation portion 43 can be referred to in FIGS. 12a, 12b, etc. The light-emitting structure 51, the second electrode portion 52, and the encapsulation portion 43 are not shown in FIGS. 4a, 4b, 5 to 10, 13a, 13b, 13c, 13d, and 13e. The structures of the light-emitting structure 51, the second electrode portion 52, and the encapsulation portion 43 can be referred to in FIGS. 12a, 12b, etc. FIGS. 4a, 4b, 5 to 13e, 15a, 15b, 16a, and 16b are cross-sectional views along the section line BB in FIG. 3.

The embodiments of the present disclosure also provide a display device, which includes a display panel, and the display panel may be the aforementioned display panel.

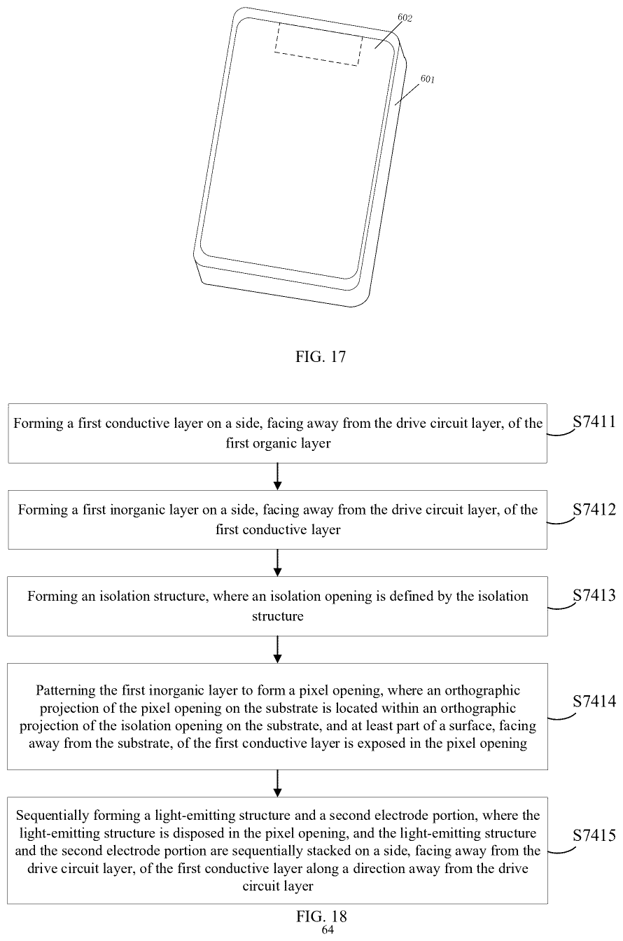

An exemplary display terminal is shown in FIG. 17, which includes a device body 601 and a display panel 602. The display panel 602 is arranged on the device body 601 and electrically connected to the device body 601. The display panel 602 is the display panel in the aforementioned embodiments, used to display static or dynamic images.

For example, the aforementioned display device can be implemented in various forms of electronic devices such as mobile phones, tablets, handheld computers, wearable devices, vehicle-mounted display devices, and more.

The above embodiments are only used to illustrate the embodiments of the present disclosure and are not intended to limit them. Those of ordinary skill in the relevant technical field may make various changes, combinations, substitutions, adjustments, and modifications without departing from the spirit and scope of the embodiments of the present disclosure. Therefore, all embodiments also fall within the scope of the embodiments of the present disclosure, and the patent protection scope of the embodiments of the present disclosure shall be defined by the claims.

What is claimed is:

1. A display panel, comprising:
a substrate;
a drive circuit layer disposed on the substrate;
a first organic layer disposed on a side, facing away from the substrate, of the drive circuit layer;
a structural function layer, a first encapsulation layer and a second encapsulation layer disposed on a side, facing away from the drive circuit layer, of the first organic layer, wherein the structural function layer, the first encapsulation layer, and the second encapsulation layer are sequentially stacked along a direction away from the drive circuit layer, the first organic layer is isolated from the first encapsulation layer by the structural function layer in at least one first region, an orthographic projection of the structural function layer on the substrate is continuous in the first region, the structural function layer comprises a first inorganic layer, a material of the first encapsulation layer comprises an organic material, and a material of the second encapsulation layer comprises an inorganic material;
an isolation structure located between the first organic layer and the first encapsulation layer, wherein a plurality of isolation openings are defined by the isolation structure; and
a plurality of light-emitting devices located between the first organic layer and the first encapsulation layer, wherein at least part of a light-emitting device is located in a corresponding one of the plurality of isolation openings.

2. The display panel according to claim 1, wherein the display panel comprises a display region and a non-display region, the non-display region comprises the first region, and the structural function layer comprises a first conductive layer and the first inorganic layer stacked along a thickness direction of the substrate;
the first conductive layer is provided with at least a first opening in the first region;
the first inorganic layer is provided with at least a second opening in the first region;
an orthographic projection of the first opening on the substrate is located outside an orthographic projection of the second opening on the substrate; and
the first inorganic layer is an inorganic insulating layer.

3. The display panel according to claim 1, wherein the display panel comprises a display region and a non-display region, the non-display region comprises the first region, the structural function layer comprises a first conductive layer and the first inorganic layer stacked along a thickness direction of the substrate;
the first conductive layer is provided with at least a first opening in the first region;
the first inorganic layer is continuous in the first region;
an orthographic projection of the first opening on the substrate is located within an orthographic projection of the first inorganic layer on the substrate; and
the first inorganic layer is an inorganic insulating layer, and the first inorganic layer has no opening in the first region.

4. The display panel according to claim 1, wherein the display panel comprises a display region and a non-display region, the non-display region comprises the first region, the structural function layer comprises a first conductive layer and the first inorganic layer stacked along a thickness direction of the substrate;
the first conductive layer is continuous in the first region;
the first inorganic layer is provided with at least a second opening in the first region;
an orthographic projection of the second opening on the substrate is located within an orthographic projection of the first conductive layer on the substrate; and
the first inorganic layer is an inorganic insulating layer, and the first conductive layer has no opening in the first region.

5. The display panel according to claim 1, wherein the display panel comprises a display region and a non-display region, the non-display region comprises the first region; the structural function layer comprises a first conductive layer and the first inorganic layer stacked along a thickness direction of the substrate;
the first conductive layer is continuous in the first region;
the first inorganic layer is continuous in the first region;
the first inorganic layer is an inorganic insulating layer, and neither the first conductive layer nor the first inorganic layer has an opening in the first region.

6. The display panel according to claim 1, wherein the display panel comprises a display region and a non-display region, the non-display region comprises the first region; the structural function layer comprises an inorganic isolation layer, a first conductive layer and the first inorganic layer stacked along a thickness direction of the substrate;
the first conductive layer is provided with at least a first opening in the first region;
the first inorganic layer is provided with at least a second opening in the first region;
an orthographic projection of the first opening on the substrate overlaps with an orthographic projection of the second opening on the substrate;
an overlapping region between the orthographic projection of the first opening on the substrate and the orthographic projection of the second opening on the substrate is located within an orthographic projection of the inorganic isolation layer on the substrate.

7. The display panel according to claim 6, wherein the inorganic isolation layer is located on a side, facing the substrate, of both the first conductive layer and the first inorganic layer;
the first inorganic layer is an inorganic insulating layer,
the inorganic isolation layer is an inorganic insulating layer;
the inorganic isolation layer is continuous in the first region; and
the inorganic isolation layer has no opening in the first region.

8. The display panel according to claim 1, wherein the display panel comprises a display region and a non-display region, the non-display region comprises the first region; the structural function layer comprises an inorganic isolation layer, a first conductive layer and the first inorganic layer stacked along a thickness direction of the substrate;
the first conductive layer is provided with at least a first opening in the first region;
the first inorganic layer is provided with at least a second opening in the first region; and
an orthographic projection of the first opening on the substrate is located outside an orthographic projection of the second opening on the substrate.

9. The display panel according to claim 8, wherein the inorganic isolation layer is located on a side, facing the substrate, of both the first conductive layer and the first inorganic layer;
the first inorganic layer is an inorganic insulating layer,
the inorganic isolation layer is an inorganic insulating layer;
the inorganic isolation layer is continuous in the first region; and
the inorganic isolation layer has no opening in the first region.

10. The display panel according to claim 1, wherein the display panel comprises a display region and a non-display region, the non-display region comprises the first region; the structural function layer comprises an inorganic isolation layer, a first conductive layer and the first inorganic layer stacked along a thickness direction of the substrate;
the first conductive layer is continuous in the first region;
the first inorganic layer is continuous in the first region; and
the inorganic isolation layer is continuous in the first region.

11. The display panel according to claim 10, wherein the inorganic isolation layer is located on a side, facing the substrate, of both the first conductive layer and the first inorganic layer;
in the first region, a boundary, away from the display region, of the inorganic isolation layer is located on a side, away from the display region, of a boundary of the first organic layer, and the boundary of the first organic layer is a boundary, away from the display region, of the first organic layer;
the first inorganic layer is an inorganic insulating layer,
the inorganic isolation layer is an inorganic insulating layer; and
the first conductive layer, the first inorganic layer and the inorganic isolation layer have no opening in the first region.

12. The display panel according to claim 1, wherein the display panel comprises a display region and a non-display region, the non-display region comprises a plurality of first regions; the structural function layer comprises a first conductive layer and the first inorganic layer stacked along a thickness direction of the substrate; the first conductive layer comprises a first sub-conductive layer and a second sub-conductive layer, the first conductive layer is provided with a plurality of first openings, the first inorganic layer is provided with one or more second openings, and the plurality of first regions comprise a first-type first region and a second-type first region;
in the first-type first region:
the first sub-conductive layer is provided with at least one of the plurality of first openings in the first-type first region;
the first inorganic layer is provided with at least one of the second openings in the first-type first region;
an orthographic projection of the first opening on the substrate is located outside an orthographic projection of the second opening on the substrate; and
in the second-type first region:
the second sub-conductive layer is provided with at least one of the plurality of first openings in the second-type first region;
the first inorganic layer is provided with at least one of the second openings in the second-type first region;
the orthographic projection of the first opening on the substrate is located outside the orthographic projection of the second opening on the substrate; or
in the second-type first region:
the second sub-conductive layer is provided with at least one of the plurality of first openings in the second-type first region;
the first inorganic layer is continuous in the second-type first region;
the orthographic projection of the first opening on the substrate is located within an orthographic projection of the first inorganic layer on the substrate.

13. The display panel according to claim 12, wherein one of the first sub-conductive layer and the second sub-conductive layer is located on a side, facing away from the substrate, of the first inorganic layer, and the other is located on a side, facing the substrate, of the first inorganic layer.

14. The display panel according to claim 13, wherein the first sub-conductive layer is arranged in a same layer as the isolation structure, the second sub-conductive layer is arranged in a same layer as a first electrode portion of the light-emitting device, and the first inorganic layer is a pixel defining layer.

15. The display panel according to claim 12, wherein the first-type first region and the second-type first region are located in at least two adjacent border regions of the display region.

16. The display panel according to claim 1, wherein the structural function layer comprises a first conductive layer and the first inorganic layer stacked along a thickness direction of the substrate,
the display panel further comprises a signal wiring line located in the first region, the signal wiring line is disposed on a side, facing away from the substrate, of the second encapsulation layer; the signal wiring line and the drive circuit layer are located on opposite sides of the first conductive layer along a direction parallel to the thickness direction of the substrate;
the drive circuit layer comprises a gate drive circuit, in the first region, the gate drive circuit and the signal wiring line are located on the opposite sides of the first conductive layer along the direction parallel to the thickness direction of the substrate; and
the signal wiring line is a touch wiring line.

17. The display panel according to claim 1, wherein the structural function layer comprises a first conductive layer and the first inorganic layer stacked along a thickness direction of the substrate,
the first region comprises a border region located on at least one border of the display region;
the at least one first region comprises a plurality of first regions, and the plurality of first regions comprise a first border region and a second border region located on opposite borders of the display region; and
the first conductive layer is located between the first inorganic layer and the substrate, or, the first inorganic layer is located between the first conductive layer and the substrate.

18. The display panel according to claim 1, wherein the structural function layer comprises a first conductive layer and the first inorganic layer stacked along a thickness direction of the substrate, the first conductive layer is located between the first inorganic layer and the substrate,
the first organic layer is provided with a via hole in the display region, the drive circuit layer comprises a pixel circuit located in the display region, the first conductive layer comprises a first electrode portion in the display region, and the first electrode portion is electrically connected to the pixel circuit through the via hole.

19. The display panel according to claim 1, wherein the first inorganic layer is a pixel defining layer,
the light-emitting device comprises a first electrode portion, a light-emitting structure, and a second electrode portion sequentially stacked in a direction away from the substrate, the first electrode portion is located between the first inorganic layer and the substrate,
the first inorganic layer is provided with a plurality of pixel openings in the display region, at least part of a surface, facing away from the substrate, of the first electrode portion is exposed by a pixel opening, and the light-emitting structure is stacked on the surface, facing away from the substrate, of the first electrode portion.

20. The display panel according to claim 1, wherein the light-emitting device comprises a first electrode portion, a light-emitting structure and a second electrode portion sequentially stacked in a direction away from the substrate, and the second electrode portion is electrically connected to the isolation structure;
the display panel further comprises a plurality of encapsulation portions, an encapsulation portion is located on a side, facing away from the substrate, of a corresponding one of the plurality of light-emitting devices, and the encapsulation portion is located between the first encapsulation layer and film layers where the light-emitting device is located; and
the light-emitting devices of different colors correspond to different encapsulation portions respectively.

21. The display panel according to claim 20, wherein at least part of the first conductive layer is arranged in a same layer as at least part of the isolation structure, or at least part of the first conductive layer is arranged in a same layer as the first electrode portion of the light-emitting device, or a part of the first conductive layer is arranged in a same layer as at least part of the isolation structure, and another part of the first conductive layer is arranged in a same layer as the first electrode portion of the light-emitting device;
the isolation structure comprises a first structural layer and a second structural layer, the first structural layer and the second structural layer are sequentially stacked in a direction toward the substrate, and a sidewall, facing the isolation opening, of the first structural layer protrudes beyond a sidewall, facing the isolation opening, of the second structural layer;
a material of the first structural layer is different from a material of the second structural layer; and
the material of the second structural layer comprises a conductive material.

22. The display panel according to claim 21, wherein the isolation structure further comprises a third structural layer, the first structural layer, the second structural layer and the third structural layer are sequentially stacked in the direction toward the substrate, and an orthographic projection of the second structural layer on the substrate is located within an orthographic projection of the third structural layer on the substrate; and
a material of the third structural layer is the same as or different from the material of the first structural layer.

23. The display panel according to claim 1, wherein the structural function layer comprises an inorganic isolation layer, a first conductive layer and the first inorganic layer stacked along a thickness direction of the substrate;
the first conductive layer is located between the first inorganic layer and the substrate,
the first organic layer is provided with at least a via hole in the display region, the inorganic isolation layer is provided with at least a third opening in the display region, an orthographic projection of the via hole on the substrate overlaps with an orthographic projection of the third opening on the substrate;
the first conductive layer comprises a first electrode portion in the display region, the first electrode portion is electrically connected to the driving circuit layer through the third opening and the via hole;
in the display region, an orthographic projection of the inorganic isolation layer on the substrate overlaps with an orthographic projection of the first inorganic layer on the substrate.

24. The display panel according to claim 1, wherein the display panel further comprises a bank located in the non-display region of the display panel, and the first region is located between the bank and the display region of the display panel.

25. The display panel according to claim 24, wherein the first encapsulation layer is located on a side, closer to the display region, of at least part of the bank, a material of the bank comprises an organic material,
the structural function layer comprises a first conductive layer and the first inorganic layer stacked along a thickness direction of the substrate, the first conductive layer is disposed on a side, facing away from the substrate, of the bank;
the first conductive layer is provided with a first through hole, an orthographic projection of the bank on the substrate overlaps with an orthographic projection of the first through hole on the substrate;
the first inorganic layer is provided with a second through hole, and an overlapping region between the orthographic projection of the first through hole on the substrate and an orthographic projection of the second through hole on the substrate overlaps with the orthographic projection of the bank on the substrate.

26. The display panel according to claim 1, wherein the display panel further comprises a bank located in a non-display region, the first encapsulation layer is located on a side, closer to the display region, of at least part of the bank, and a material of the bank comprises an organic material;
the structural function layer comprises an inorganic isolation layer, a first conductive layer and the first inorganic layer stacked along a thickness direction of the substrate, the inorganic isolation layer is located on a side, closer to the display region, of the bank;
the first conductive layer is located on a side, closer to the display region, of the bank;
and the first inorganic layer is provided with a second through hole, and an orthographic projection of the bank on the substrate overlaps with an orthographic projection of the second through hole on the substrate.

27. A manufacturing method for a display panel, the manufacturing method comprising:
providing a substrate,
sequentially forming a driving circuit layer and a first organic layer on the substrate;
baking the first organic layer;
sequentially forming a structural function layer, a first encapsulation layer, and a second encapsulation layer on a side, facing away from the driving circuit layer, of the first organic layer, wherein in at least a first region, the first encapsulation layer is isolated from the first organic layer by the structural function layer.

28. The manufacturing method for the display panel according to claim 27, wherein the forming the structural function layer on the side, facing away from the driving circuit layer, of the first organic layer, comprises:
forming a first conductive layer on the side, facing away from the driving circuit layer, of the first organic layer;
forming a first inorganic layer on a side, facing away from the driving circuit layer, of the first conductive layer;
wherein the display panel comprises a display region and a non-display region, the non-display region comprises the first region; the first conductive layer is provided with at least a first opening in the first region, the first inorganic layer is provided with at least a second opening in the first region, and an orthographic projection of the first opening on the substrate is located outside an orthographic projection of the second opening on the substrate; or
the first conductive layer is provided with the first opening in the first region, the first inorganic layer is continuous in the first region, and the orthographic projection of the first opening on the substrate is located within an orthographic projection of the first inorganic layer on the substrate; or
the first conductive layer is continuous in the first region, the first inorganic layer is provided with the second opening in the first region, and the orthographic projection of the second opening on the substrate is located within an orthographic projection of the first conductive layer on the substrate; or
the first conductive layer is continuous in the first region, and the first inorganic layer is continuous in the first region.

29. The method for preparing a display panel according to claim 27, wherein the forming the structural function layer on the side, facing away from the driving circuit layer, of the first organic layer comprises:
sequentially forming an inorganic isolation layer, a first conductive layer, and a first inorganic layer on the side, facing away from the driving circuit layer, of the first organic layer, wherein in the first region, the inorganic isolation layer covers the first organic layer;
wherein the display panel comprises a display region and a non-display region, the non-display region comprises the first region, and the inorganic isolation layer is continuous in the first region;
after the forming the structural function layer and before the forming the first encapsulation layer and the second encapsulation layer, the method further comprises:
forming an isolation structure, wherein at least an isolation opening is defined by the isolation structure; and
forming at least part of film layers of at least a light-emitting device and an encapsulation portion located on a side, facing away from the substrate, of the light-emitting device, wherein at least part of the light-emitting device is located in the isolation opening.

30. A display device, comprising the display panel according to claim 1.
